(19) United States
(12) Patent Application Publication
(10) Pub. No.: US 2012/0315728 A1
(43) Pub. Date: Dec. 13, 2012

(54) Saw Type Package without Exposed Pad

(75) Inventors: Elite Lee, Shanghai (CN); Dana Liu, Shanghai (CN)

(73) Assignee: SHANGHAI KAIHONG ELECTRONIC COMPANY LIMITED, Shanghai (CN)

(21) Appl. No.: 13/158,219

(22) Filed: Jun. 10, 2011

(51) Int. Cl. H01L 21/60; H01L 21/78

(52) U.S. Cl. 438/113; 257/E21.506; 257/E21.599

(57) ABSTRACT

In one embodiment, a method for manufacturing a saw type pad is provided. The method includes performing a first molding process to form a first molded layer beneath a pad of a lead frame. A semiconductor device is placed on the pad. A second molding process is performed to form a second molded layer. The first molded layer and the second molded layer form an encapsulation to enclose the semiconductor device and the pad. The lead frame is singulated to form an individualized semiconductor package. The pad is not exposed from a bottom surface of the semiconductor package.

### BACKGROUND

Particular embodiments generally relate to a package without an exposed pad.

Electrical devices have become smaller and more lightweight. These devices thus have less room to lay out all the electrical functional units (e.g., integrated circuit (IC) chips) in the device's body. This requires that the electrical functional units have a thin thickness.

A saw-type package may be a thinner type package. The saw-type package also has a high unit density where more than tens of thousands of packages may be on one strip. FIG. 1 depicts an example of a conventional saw-type package. The saw-type package may be a no-lead package with a lead frame and wire bonding. The package includes an exposed pad 102, leads 104, an adhesive die attach material 106, an IC chip 108, and wire bonds 110. An encapsulation compound 112 encapsulates pad 102, leads 104, chip 108, and wire bonds 110. The encapsulation is performed using a single molding step with a mold chase.

As shown, pad 102 is exposed from a bottom surface of molding compound 112. The exposed pad helps heat transfer out of IC chip 108.

This encapsulation method is suitable for encapsulating elements that are very thin and have very small sizes. The QFN process has very high integration level, which can integrate more than ten thousand encapsulation units on one encapsulation tape; moreover, the process is very flexible in that the same equipment can be used as long as elements to be encapsulated have the same outside dimension, such as molding tools and trim and form tools. Therefore, the QFN encapsulation process can shorten the cycle of encapsulation R&D and lower the cost of processing tools.

Although the thermal sink in the QFN encapsulation structure is favorable for heat dissipation of the chip during operations, it results in deteriorated insulation properties between conductive pins of an encapsulated unit. For chips with low heat generation, users often give higher priority to excellent insulation properties between conductive pins of the encapsulated units, making the presence of a conductive thermal sink unnecessary due to the consequent deteriorated insulation properties between the pins. As far as QFN processes are concerned, however, there is an exposed conductive thermal sink at the bottom of an encapsulated unit, which limits fields that the QFN process can be applied in.

### SUMMARY

In one embodiment, a method for manufacturing a saw type pad is provided. The method includes performing a first molding process to form a first molded layer beneath a pad of a lead frame. A semiconductor device is placed on the pad. A second molding process is performed to form a second molded layer. The first molded layer and the second molded layer form an encapsulation to enclose the semiconductor device and the pad. The lead frame is singulated to form an individualized semiconductor package. The pad is not exposed from a bottom surface of the semiconductor package.

In one embodiment, the method includes placing a top mold chase on a top surface of the lead frame and placing a bottom mold chase on a bottom surface of the lead frame.

In one embodiment, the top mold chase has a flat surface that is placed above the top surface of the lead frame.

In one embodiment, the first molded layer supports the pad during a wire bonding process to attach the wire bond.

In one embodiment, the first molded layer supports the pad during a die bonding process to place the semiconductor device on the pad.

In one embodiment, a method includes placing a first mold chase above a top surface of a lead frame. The first mold chase has a flat surface on a portion facing the top surface of the lead frame. The method further includes placing a second mold chase on a bottom surface of the lead frame and molding a first molded layer beneath a pad of the lead frame. A semiconductor device is placed on the pad. The method then includes placing a third mold chase on the top of the lead frame to form a cavity and molding a second molded layer in the cavity. The first molded layer and the second molded layer enclose the semiconductor device and the pad. The lead frame is sawed to form an individualized semiconductor package.

In one embodiment, the third mold chase is in a shape to form the cavity before molding the second molded layer and the first mold chase is in a shape to leave the pad exposed after molding the first molded layer.

In one embodiment, the first molded layer supports the pad during a die bonding process to place the semiconductor device on the pad.

The following detailed description and accompanying drawings provide a better understanding of the nature and advantages of the present invention.

### BRIEF DESCRIPTION OF THE DRAWINGS

FIG. 1 depicts an example of a conventional saw-type package.

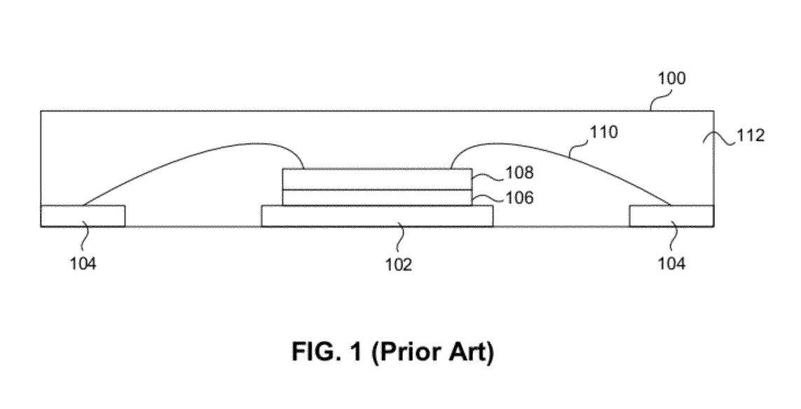

FIG. 2 depicts a method for manufacturing a package according to one embodiment.

FIG. 3 shows an example of a top mold chase and a bottom mold chase according to one embodiment.

FIG. 4a and FIG. 4b show a more detailed example of a lead frame and a molding compound according to one embodiment.

FIGS. 5a and 5b show the package after a de-tape process according to one embodiment.

FIGS. 6a and 6b show a top view and a bottom view of the package after a die bonding process according to one embodiment.

FIGS. 7a and 7b show a top view and a bottom view, respectively, of the package after wire bonding according to one embodiment.

FIG. 8 shows a more detailed example of the package according to one embodiment.

FIGS. 9a and 9b show a top view and a bottom view of the package after singulation according to one embodiment.

### DETAILED DESCRIPTION

Described herein are techniques for a package without an exposed pad. In the following description, for purposes of explanation, numerous examples and specific details are set forth in order to provide a thorough understanding of embodiments of the present invention. Particular embodiments as defined by the claims may include some or all of the features in these examples alone or in combination with other features described below, and may further include modifications and equivalents of the features and concepts described herein.

Particular embodiments provide a package without an exposed pad. For example, a saw-type package does not have an exposed pad. The no-exposed pad package may use a pre-molding process in addition to a molding process to form the no-exposed pad package. In one embodiment, a quad flat no-lead encapsulation structure and encapsulation method is provided, such that there is no longer an exposed conductive thermal sink at the bottom of an encapsulated unit, consequently improving insulation properties between the pins.

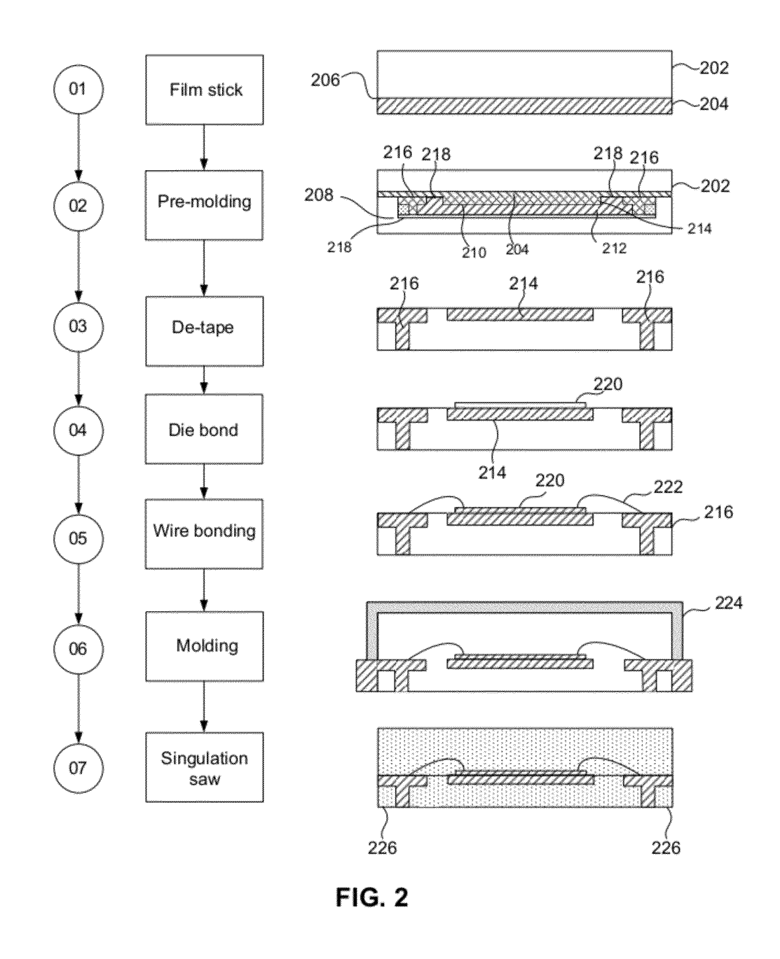

FIG. 2 depicts a method for manufacturing a package according to one embodiment. At 01, a top mold chase 202 has a soft film 204 with a vicious surface placed on a surface of top mold chase 202. Soft film 204 may be adhered to the bottom surface of top mold chase 202. Soft film 204 may be a blue film. Top mold chase 202 may be a plate and formed in a rectangular shape. Other shapes may also be used. The plate may have a flat bottom surface 206. Flat bottom surface 206 may be placed above a top surface of a lead frame, which will be described below. Soft film 204 protects the top surface of the lead frame from being contaminated by a molding compound during a pre-molding step. The role of film 204 is to prevent flash in subsequent injection molding processes. In order to maintain the flatness of film 204 for smooth implementation of subsequent processes, film 204 can be placed on a solid flat surface, or certain tensile force can be applied on two ends of film to ensure the flatness of film 204.

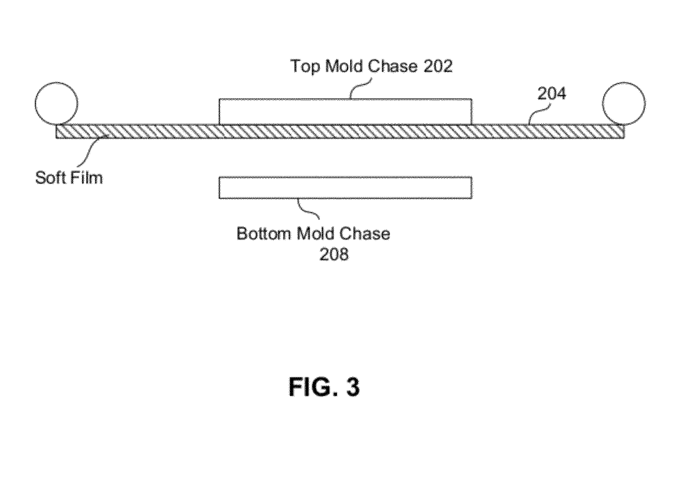

A bottom mold chase 208 may also be used. Bottom mold chase 208 and top mold chase 202 form a chase system. FIG. 3 shows an example of a top mold chase 202 and bottom mold chase 208 according to one embodiment. As shown, soft film 204 is adhered to top mold chase 202. Bottom mold chase 208 may be clamped onto top mold chase 202 to form the chase system. In one example, bottom mold chase 208 is a rectangular shape similar to the shape of top mold chase 202. Additionally, although not shown, bottom mold chase 208 may include side portions that may couple to top mold chase 202. For example, bottom mold chase 208 may be in a U-shape such that a cavity is formed.

Referring back to FIG. 2, at 02, a pre-molding step is performed. The pre-molding step molds a half-etched part of a lead frame 210. The half-etched part may be the part that is below a top surface of lead frame 210, such as the half-etched parts shown on leads (pins) 216. The adhesive used may be an epoxy molding compound.

Bottom mold chase 208 and top mold chase 202 are clamped together. Soft film 204 is in between bottom mold chase 208 and top mold chase 202 and also on a top surface of lead frame 210. Soft film 204 may be caved in through apertures on the top surface of lead frame 210. For example, in apertures 218, the soft film has been pushed downward. The caved portion of the soft film can be contacted to closely and make sure no flash on the top surface of lead frame.

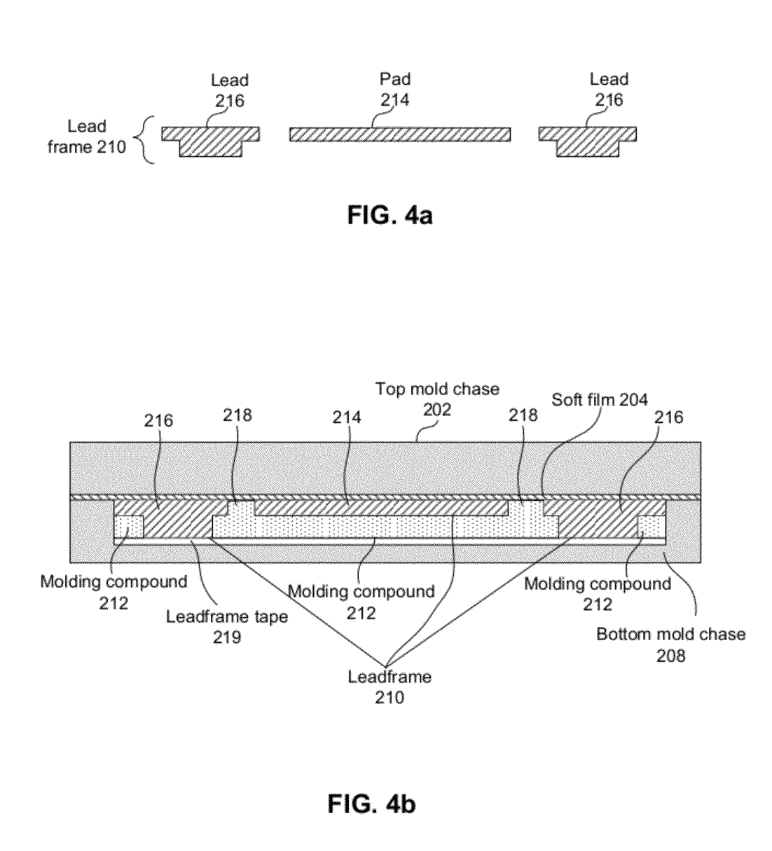

FIG. 4a and FIG. 4b show a more detailed example of lead frame 210 and molding compound 212 according to one embodiment. FIG. 4a shows just lead frame 210. Lead frame 210 includes a pad 214 and leads 216. Leads 216 may be in the form of a T-shape and include ledges that hold leads 216 in place when leads 216 are encapsulated by molding compound 212.

Lead frame 210 includes a plurality of mutually insulated pins, which are represented by leads 216 in this embodiment. Each pin comprises a first end adhered to the viscous surface of the film 204 and a second end opposite the first end, the width of said second end being smaller than the width of the first end, as shown by the shapes of leads 216. The advantage of the above shapes of the pins is that it ensures the firmness of the pins after encapsulation. In a completed encapsulation structure, the first ends of leads 216 in this step are encapsulated in the insulation adhesive, while the surfaces of the second ends are exposed. Although the friction between the insulation adhesive and the pins can secure the lead frame 210, an inward pressure can be further generated from the insulation adhesive on the lead frame 210 by making the width of the second end smaller than that of the first end, which can further ensure that the lead frame 210 is firmly embedded into the encapsulation structure that has been completed, and not easy to fall apart.

Pad 214 may be rectangular in shape. As shown, pad 214 is on a same plane as a top portion of leads 216. For example, the top surface of pad 214 and leads 216 may be in line with each other. Thus, pad 214 is raised with respect to a bottom surface of leads 216.

As shown in FIG. 4b, lead frame 210 is surrounded by bottom mold chase 208 and top mold chase 202. Lead frame tape 219 is placed in between lead frame 210 and bottom mold chase 208. Lead frame tape 219 may hold lead frame 210. Also, lead tape frame 219 may prevent a bottom portion of leads 216 from being contaminated by molding compound 212. A cavity is formed where a molding compound 212 may be inserted into the cavity. As shown, molding compound 212 may be inserted under half-etched portions of leads 216 and also under pad 214 to form a first molded layer. The first molded layer may be underneath the T-portion of leads 216 and underneath pad 214. This supports pad 214 and leads 216. Also, the first molded layer may fill apertures 218 up to a level around the top surface of lead frame 210. In one embodiment, top mold chase 202 is flat and placed on top of lead frame 210 such that first molded layer is not formed above lead frame 210.

In this step, the depth of the chamber is not smaller than the thickness difference between the lead frame 210 and pad 214. Since the thickness of the lead frame 210 is greater than the thickness of the pad 214, the depth of the chamber may be no smaller than the thickness difference between lead frame 210 and pad 214 so as to ensure that pad 214 can be immersed into molding compound 212, instead of being isolated on the surface of molding compound 212 such that it is consequently removed together with film 204 in subsequent steps, making it impossible to carry out subsequent processes.

In this embodiment, since lead frame 210 and pad 214 are adhered to the surface of the film 204, this step needs to first cover film 204 with a viscous surface on the surface of the first injection mould 150, and the chip base 110 and the lead frame 130 are disposed inside the chamber; then, fill up the chamber with molding compound 212; and then, cure molding compound 212. Molding compound 212 can also be injected into the chamber first, and then place lead frame 210 and pad 214. The effect of this step is to cover lead frame 210 and pad 214 with molding compound 212. When this step is carried out, pad 214 and lead frame 210 are partially covered by molding compound 212.

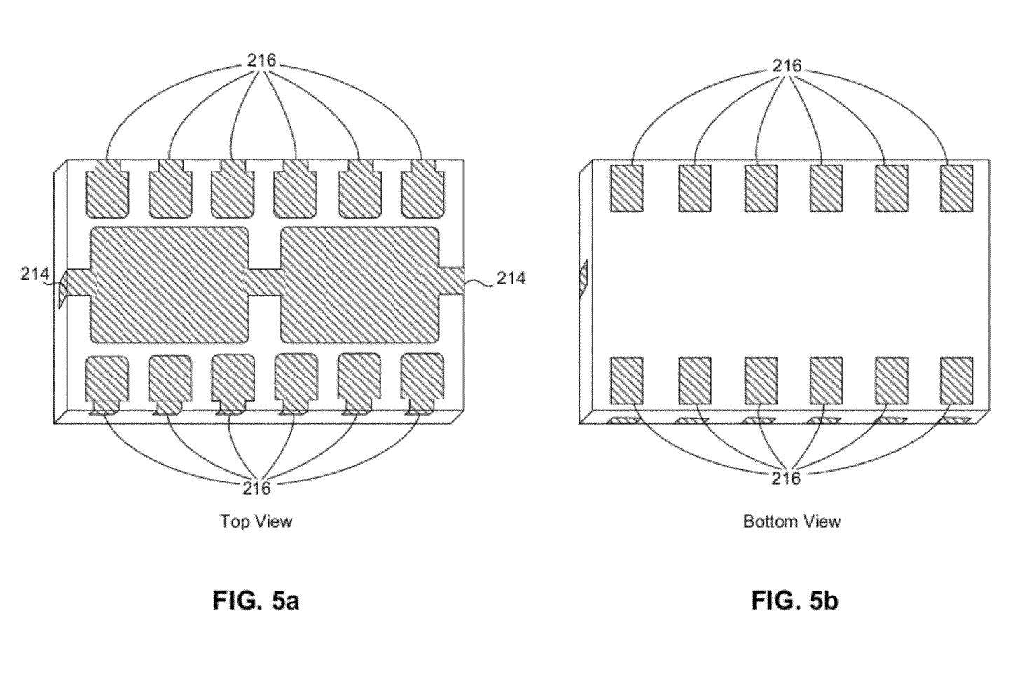

Referring back to FIG. 2, at 03, a de-tape process is performed. Soft film 204 and lead frame tape 219 are removed. Both ends of leads 216 of lead frame 210 are exposed, and the surface of pad 214 originally adhered to film 204 is exposed as well. FIGS. 5a and 5b show the package after de-tape process according to one embodiment. FIG. 5a shows a top view of the package. As shown, multiple pads 214 are exposed on the top after the de-tape. Additionally, leads 216 are exposed on the top portion. In contrast, referring to FIG. 5b, leads 216 are exposed on a bottom portion, but pads 214 are not exposed on the bottom portion.

Referring back to FIG. 2, at 04, a die bonding process is performed. A semiconductor device, such as a semiconductor die 220, may be bonded to pad 214. A die bond machine may be used to perform die bonding. Conductive silver paste may be used or other vicious materials. The die in this step refers to wafer grains cut from a whole wafer with a plurality of electrically connected electronic components fabricated thereon.

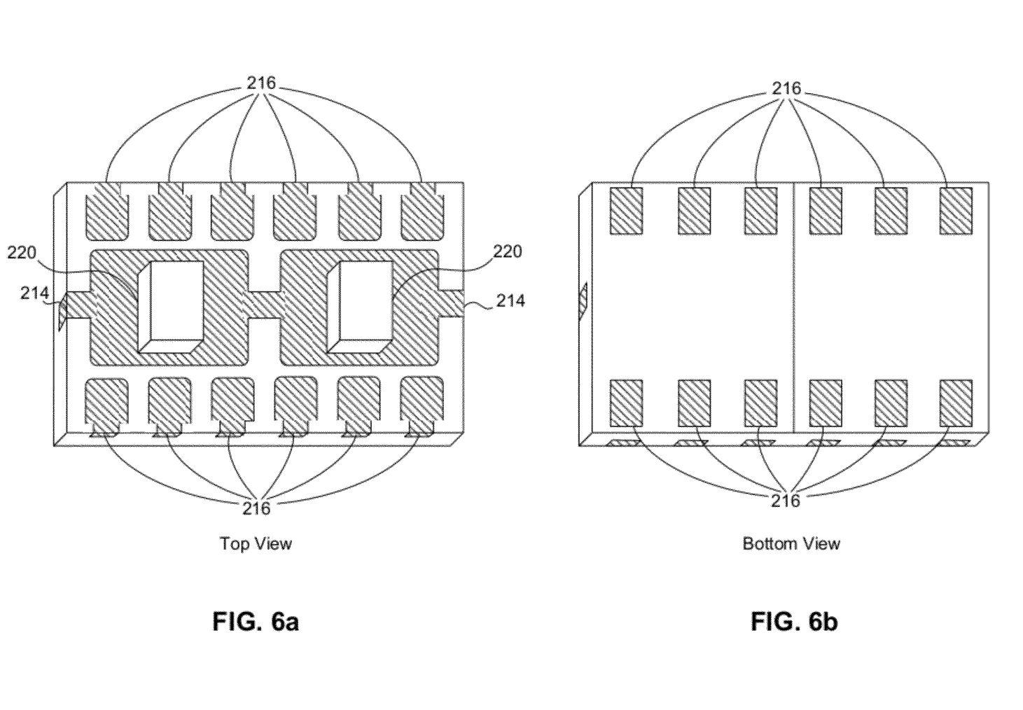

FIGS. 6a and 6b show a top view and a bottom view of the package after die bonding process according to one embodiment. Semiconductor die 220 is shown on top of pads 214 on the top portion in FIG. 6a. In FIG. 6b, leads 216 are exposed on the bottom view.

During die bonding, molding compound 212 supports pad 214 to allow semiconductor die 220 to be bonded to pad 214. Because of the size of pad 214, regular tools may not be used to support pad 214 if molding compound 212 was not used. Regular tools without supporting area design cannot support the pad 214 because the pad is floating. Special tools with supporting area design can be used to support the pad 214, but special tools cost is high. Thus, pre molding compound is applied to support the floating pad. Also, if an extra pad was inserted below pad 214 to support pad 214, the extra pad may be too small to manufacture and also would add cost to the manufacture of the package due to the tools needed and also the cost of manufacturing the extra pad separately.

Referring back to FIG. 2, at 05, wire bonding is performed. A wire bond machine may be used to attach wire bonds 222 from semiconductor die 220 to leads 216. Wire bonds 222 may be made from a material, such as aluminum, gold, or copper. Wire bonds 222 are attached from a top surface of leads 216 to semiconductor die 220. For example, pads on the surface of the chip are electrically connected with corresponding pins of the lead frame via wires. Although wire bonding is discussed, other methods of connecting semiconductor die 220 to leads 216 may be used.

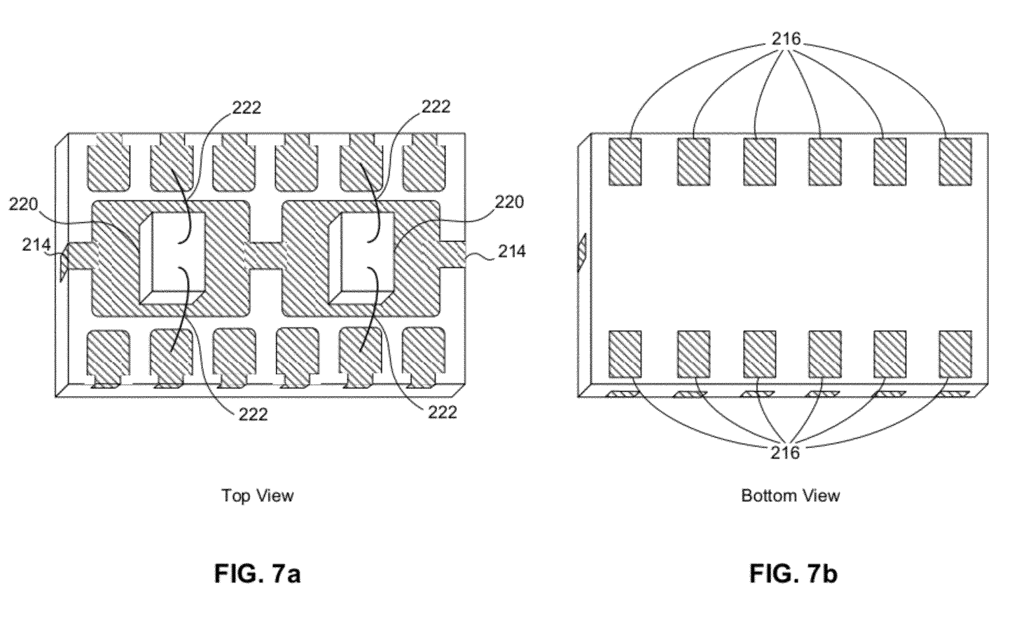

FIGS. 7a and 7b show a top view and a bottom view, respectively, of the package after wire bonding according to one embodiment. In FIG. 7a, wire bonds 222 couple semiconductor die 220 to leads 216. The isolation of conductivity and electric currents between pads 214 is strengthened by not having pads 214 exposed. This is because pads 214 are not exposed and surrounded by molding. Referring to FIG. 7b, leads 216 are exposed on the bottom portion.

During wire bonding, molding compound 212 supports pad 214 to allow wire bonds 222 to be bonded to semiconductor die 220. Because of the size of pad 214, regular tools may not be used to support pad 214 if molding compound 212 was not used.

Referring back to FIG. 2, at 06, a molding process is performed. This is a second molding process that is performed after the previously performed pre-molding process. In this case, a top mold chase 224 is used. Top mold chase 224 is different from top mold chase 202 that was used in the pre-molding process. For example, top mold chase 224 has a cavity and top mold chase 202 was flat. The depth of the chamber of the second molding process should be greater than the thickness of die 220, and there should be a certain difference between the two so as to ensure a sufficient space for the wires in the chamber.

In one embodiment, it is probable that dozens, hundreds or even thousands of sets of the above structure composed of lead frame and pad can co-exist on one same film to form an array of multiple rows and multiple columns on the surface of the film. Correspondingly, the employed injection molding die comprises a plurality of chambers for carrying out the injection molding process. To an encapsulation structure with a plurality of array structures, therefore, a cutting process is further carried out to separate each element after the above steps to obtain independent encapsulation units.

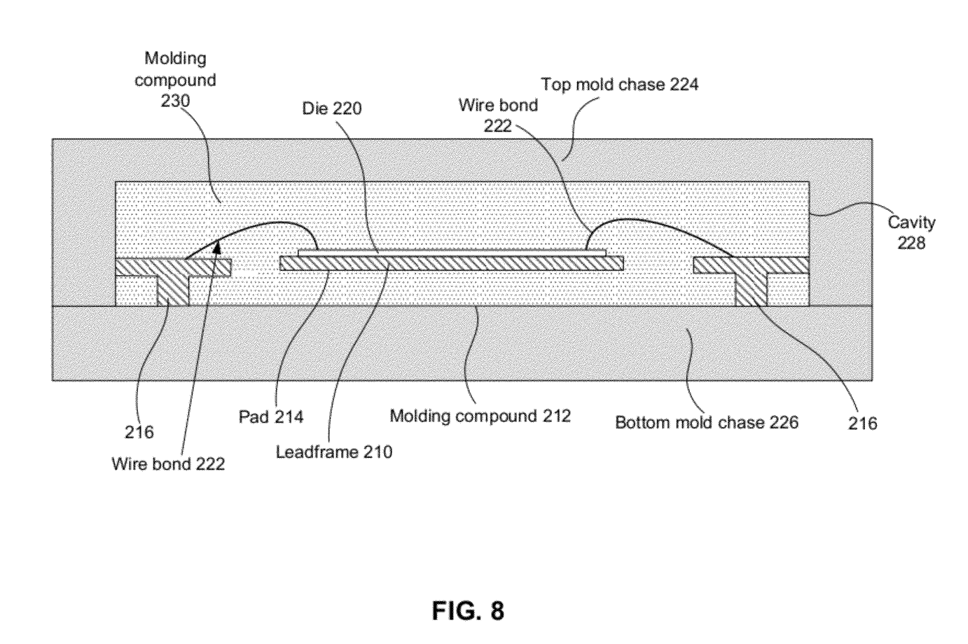

FIG. 8 shows a more detailed example of the package according to one embodiment. Top mold chase 224 is coupled to bottom mold chase 226. Top mold chase 224 is formed in a U-shape that includes a cavity 228. Cavity 228 is located above a top portion of lead frame 210, semiconductor die 220, and wire bonds 222. In one example, bottom mold chase 226 may be similar to bottom mold chase 208, but that is not necessary. For example, bottom mold chase 226 may be a rectangular-shape or U-shape. Bottom mold chase 220 is placed on a bottom surface of molding compound 212 and leads 216.

A molding compound 230 is inserted into cavity 228. Molding compound 230 encapsulates semiconductor die 220, wire bonds 222, and lead frame 210 in a second molding layer. The first molding layer and second molding layer may form a single molding layer. For example, molding compound 230 is coupled with molding compound 212 to form a single encapsulation of lead frame 210, wire bonds 222, and semiconductor die 220. Also pad 214 is not exposed on a bottom portion of the package.

Accordingly, two molding processes, a pre-molding process and a molding process, are performed. A pre-molding process allows a molding layer to be inserted below pad 214 such that it is not exposed from the package and also supports pad 214 during the die bonding and wire bonding process. A second molding process then encapsulates semiconductor die 220.

Referring back to FIG. 2, at 07, a singulation process is performed. For example, a singulation sawing process is used. The package is sawed at singulation points. A blade may be used to saw the encapsulation and lead frame 210. Individual devices are then formed. Using the saw process also allows high unit density as tens of thousands (or more) of packages may be formed on a strip and singulated using the saw.

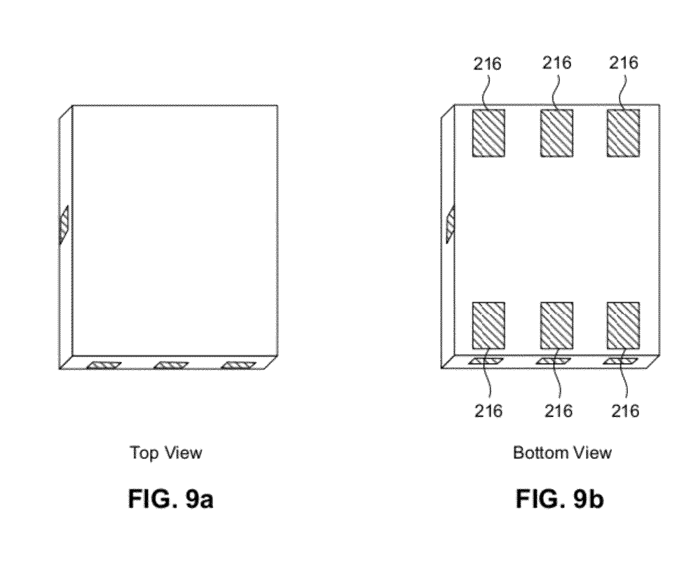

FIGS. 9a and 9b show a top view and a bottom view of the package after singulation according to one embodiment. As shown, the top view does not have any components exposed. On the bottom view, leads 216 are exposed, but pad 214 is not exposed.

Accordingly, a pad below a lead frame does not have to be added. Using the pre-molding process, particular embodiments form a first layer below pad 214. This provides a molding layer below pad 214 and avoids having to insert an extra pad below pad 214. This may be less costly than adding a pad in the packaging process. No extra tooling may be used to support the pad also. Further, the non-exposed pad 214 strengthens and reinforces the isolation of connectivity and electric currents between pads 214.

Particular embodiments has an advantage in that by employing a chip base thinner than the thickness of the lead frame and by further employing a flat film with a viscous surface for adhering one surface of the chip base and the lead frame to the same plane, the other surface of the chip base is disposed lower than the lead frame. As a result, the above technique can ensure that the chip base is completely covered by the insulation adhesive and will not be exposed in subsequent processes, thus improving insulation properties between pins.

As used in the description herein and throughout the claims that follow, “a”, “an”, and “the” includes plural references unless the context clearly dictates otherwise. Also, as used in the description herein and throughout the claims that follow, the meaning of “in” includes “in” and “on” unless the context clearly dictates otherwise.

The above description illustrates various embodiments of the present invention along with examples of how aspects of the present invention may be implemented. The above examples and embodiments should not be deemed to be the only embodiments, and are presented to illustrate the flexibility and advantages of the present invention as defined by the following claims. Based on the above disclosure and the following claims, other arrangements, embodiments, implementations and equivalents may be employed without departing from the scope of the invention as defined by the claims.

What is claimed is:

1. A method comprising:
performing a first molding process to form a first molded layer beneath a pad of a lead frame;
placing a semiconductor device on the pad;
performing a second molding process to form a second molded layer, wherein the first molded layer and the second molded layer to form an encapsulation to enclose the semiconductor device and the pad; and
singulating the lead frame to form an individualized semiconductor package,
wherein the pad is not exposed from a bottom surface of the semiconductor package.

2. The method of claim 1, wherein performing the first molding process comprises:
placing a top mold chase on a top surface of the lead frame; and
placing a bottom mold chase on a bottom surface of the lead frame.

3. The method of claim 2, further comprising placing a film on the top mold chase, the film being in between the top mold chase and the top surface of the lead frame.

4. The method of claim 3, wherein the film is partially caved in on a side portion of the lead frame.

5. The method of claim 3, removing the film after performing the first molding process.

6. The method of claim 2, wherein the top mold chase has a flat surface that is placed above the top surface of the lead frame.

7. The method of claim 1, wherein performing the second molding process comprises placing a top mold chase on a top of the lead frame to form a cavity.

8. The method of claim 7, further comprising forming the second molded layer inside the cavity, wherein the second molded layer contacts the first molded layer to form the encapsulation to enclose the semiconductor device and the pad.

9. The method of claim 1, further comprising attaching a wire bond from the semiconductor device to a portion of the lead frame.

10. The method of claim 9, wherein the first molded layer supports the pad during a wire bonding process to attach the wire bond.

11. The method of claim 1, wherein singulating comprises sawing through the lead frame to form the semiconductor package.

12. The method of claim 1, wherein the first molded layer supports the pad during a die bonding process to place the semiconductor device on the pad.

13. The method of claim 1, further comprising adding lead frame tape to a bottom surface of the lead frame to support the lead frame during the first molding process.

14. A method comprising:
placing a first mold chase above a top surface of a lead frame, wherein the first mold chase has a flat surface on a portion facing the top surface of the lead frame;
placing a second mold chase on a bottom surface of the lead frame;
molding a first molded layer beneath a pad of the lead frame;
placing a semiconductor device on the pad;
placing a third mold chase on the top of the lead frame to form a cavity;
molding a second molded layer in the cavity, wherein the first molded layer and the second molded layer enclose the semiconductor device and the pad; and
sawing the lead frame to form an individualized semiconductor package.

15. The method of claim 14, further comprising placing a film on the first mold chase, the film being in between the first mold chase and the top surface of the lead frame.

16. The method of claim 15, further comprising removing the film after molding the first molded layer.

17. The method of claim 14, wherein:
the third mold chase is a shape to form the cavity before molding the second molded layer; and
the first mold chase is in a shape to leave the pad exposed after molding the first molded layer.

18. The method of claim 14, wherein the first molded layer supports the pad during a die bonding process to place the semiconductor device on the pad.

19. The method of claim 14, further comprising attaching a wire bond from the semiconductor device to a portion of the lead frame.

20. The method of claim 19, wherein the first molded layer supports the pad during a wire bonding process to attach the wire bond.
